(19) United States
(12) Patent Application Publication
(10) Pub. No.: US 2010/0066570 A1
(43) Pub. Date: Mar. 18, 2010

(54) QWERTY keypad

(76) Inventors: Guy LH Tessens, Georgetown (MY); Steven R. Takayama, Atherton, CA (US)

Correspondence Address: Lawrence J. Shurupoff, 16651 Topanga Ln., Delray Beach, FL, 33484, US

(21) Appl. No.: 12/586,270

(22) Filed: Sep. 16, 2009

Related U.S. Application Data
(60) Provisional application No. 61/192,108, filed on Sep. 16, 2008.

(51) Int. Cl. H03M 11/00

(52) U.S. Cl. 341/22

(57) ABSTRACT

Larger keys can be arranged on a given QWERTY keyboard area by providing nine keys on each of three rows and positioning a single key, such as the key typically representing the letter “P”, above the top row of keys. This can provide about a ten percent (10%) increase in key size surface area in about the same keyboard surface space or a larger lateral or horizontal spacing between each key for the same size of keys.

### CROSS REFERENCE TO RELATED APPLICATIONS

This application claims the benefit and priority of U.S. provisional patent application No. 61/192,108 filed on Sep. 16, 2008 entitled “QWERTY Keypad” and is incorporated herein by reference in its entirety.

### BACKGROUND AND SUMMARY

The cramped spacing of relatively small alphanumeric keys and other keys on compact portable electronic devices results in difficult keyboard operation and potential operator error. Hand held electronic devices such as cellular telephones, calculators, personal digital assistants, computers and the like typically include keypads with several rows of ten tightly spaced miniature buttons or keys. The tight spacing is defined by the available space on the surface of typically compact hand-held electric devices and often results in a user mistakenly pushing an adjacent key rather than the intended key.

These conventional keypads and keyboards are referred to as “QWERTY” keypads and keyboards as the top row of ten alphanumeric characters displays from left to right the Q key, the W key, the E key, the R key, the T key, the Y key, the U key, the I key, the O key and the P key.

In accordance with this disclosure, it has been found that a set of larger keys and/or buttons can be provided on virtually the same given keyboard area by arranging a QWERTY keypad or keyboard in several rows having only nine keys in each row, and by moving one key (previously located in a row of ten keys) above the top row of the remaining nine keys, or otherwise moving one key outside the top row of the remaining nine keys. Having nine instead of ten keys in a row allows each key to be enlarged in width and area by about 10% larger than having ten keys in the same row space. The larger keys and/or potentially larger distance between keys (if the key size stays the same) reduces user error and provides a more user-friendly keyboard, especially for users having large fingers and thumbs.

The individual key buttons can be formed or attached in groups of three keys, two keys and single keys as seen in FIG. 1. In this example the Q, S and E buttons are grouped together somewhat in a pattern of a “Y” or “V”. The F, T and H buttons are grouped together somewhat in the pattern of an inverted “Y” or “V”, and the U, K and O buttons on the top two rows of buttons or keys are grouped together somewhat in the pattern of a “Y” or “V”. The A, Z and D buttons, C, G and B buttons and J. M and L buttons can also be respectively linked in integral groups of three buttons each on the second and third rows of buttons or keys. The star, V and pound buttons can be similarly linked on the third and forth rows. This arrangement of larger keys allows for improved keyboard accuracy and improved and faster text messaging with fewer mistakes.

### BRIEF DESCRIPTION OF THE DRAWINGS

In the drawings:

FIG. 1 is a top plan view of a keypad assembly constructed in accordance with one embodiment of this disclosure;

FIG. 2 is an exploded view of the keypad assembly construction of FIG. 1;

FIG. 3 is a top front perspective view of the keypad assembly of FIG. 2;

FIG. 4 is an elevation view taken along lines 4-4 of FIG. 3;

FIG. 5 is an elevation view taken along lines 5-5 of FIG. 3;

FIG. 6 is a top plan view of three keypad keys or buttons formed as an integral unit;

FIG. 7 is a view in section through line 7-7 of FIG. 1;

FIG. 8 is a view in section through line 8-8 of FIG. 1;

FIG. 9 is a top plan view of a co-molded rubber pad and light guide assembly;

FIG. 10 is a left side elevation view of FIG. 3;

FIG. 11 is an enlarged view of region A of FIG. 7; and

FIG. 12 is a view of FIG. 11 showing a key or button in a depressed and actuated position.

In the various views of the drawings, like reference numerals designate like or similar parts.

### DETAILED DESCRIPTION OF REPRESENTATIVE EMBODIMENTS

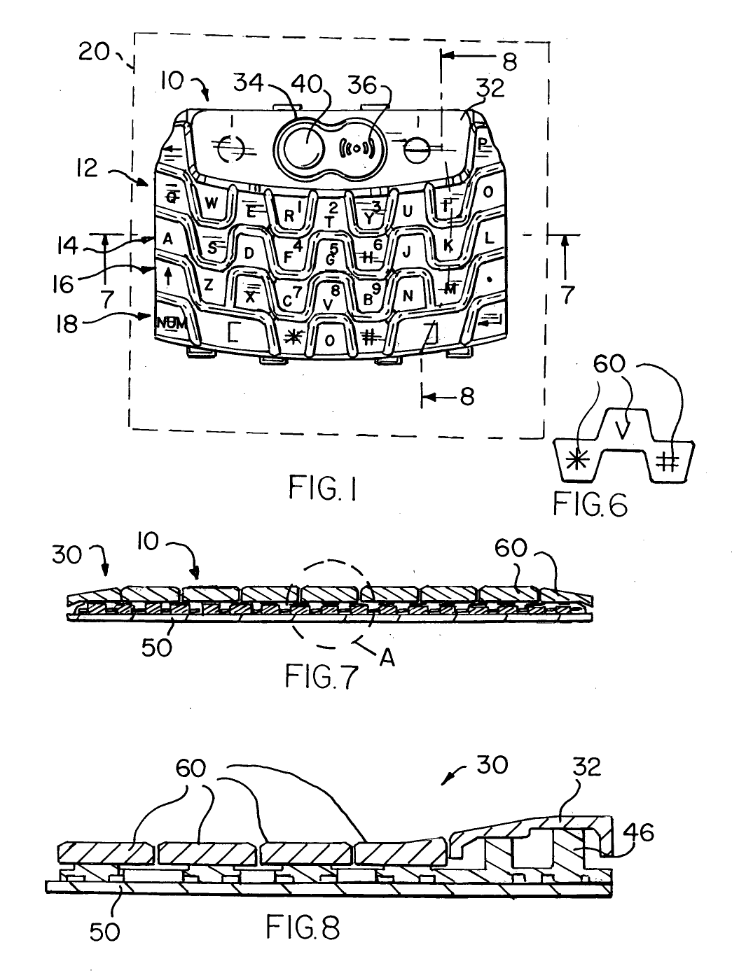

This disclosure is directed to improving the operation, use and consumer acceptance of compact electronic keyboards or keypads as used in, for example, hand-held telephones such as “smart” phones. The compact keypad 10, as shown in FIG. 1, provides a solution to the problem of cramped spacing of the alphanumeric keys which take up the majority of space on a keyboard or keypad. Instead of arranging ten evenly spaced keys on the top row 12, only nine evenly spaced keys or buttons are provided on the top row 12. This not only provides a better “open” tactile feel, but also provides about a ten percent (10%) increase in keypad surface area available for each key or button. This provides more space for an operator's thumbs or fingers to maneuver each key. This reduces the chance of an operator inadvertently engaging or depressing another key adjacent to the intended key.

In order to reduce the number of keys or buttons from ten to nine in the top row 12, the right upper corner key or button, which corresponds to the letter “P” key in a traditional ten key upper row of keys or buttons, is moved to a position above or outside of the top row 12. In the example seen in FIG. 1, the “P” key or button has been moved from its traditional location on a QWERTY keypad, to a position located above the top row 12. In particular, the “P” key or button has been moved to a position directly above the letter “O” key. In this manner, the “P” key or button is still located in an upper right corner area of the keypad 10 so that it is easy for an operator to adapt to using this new keypad arrangement. No significant change of an operator's memory of key or button location and use of the keypad 10 is required, other than a slight upward reach for the letter “P.” Stated another way, the letter “P” key, which is traditionally positioned on the right of the letter “O” key, is relocated above the letter “O” key so that only a small change in finger or thumb movement is required to operate the new keypad.

As further seen in FIG. 1, the keyboard 10 is laid out symmetrically with the first three rows of nine keys each having a key area of about the same size. The top row 12 includes nine keys with keyboard symbols respectively labeled from left to right as the “Q;” key, the “W (” key, the “E)” key, the “R1” key, “T2” key, the “Y3” key, the “U+” key, the “I@” key and the “O“” key. The next or second row 14 from the top row 12 also includes nine keys with keyboard symbols respectively positioned in order directly below the nine keys in the top row 12. The keys in the second row 14 are labeled from left to right as “A&” key, the “S—” key, the “D$” key, the “F4” key, the “G5” key, the “H6” key, the “J/” key, the “K:” key and the “L,” key.

Directly below the second row 14 is a third row 16 of nine keys with keyboard symbols each aligned directly below the respective nine keys in the second row 14. The nine keys in the third row 16 align with the nine keys in each of the first and second rows to form nine vertically-aligned columns of three keys each.

The third row 16 has keys labeled with keyboard symbols or characters from left to right as the “?” key, the “Z%” key, the “X=” key, the “C7” key, the “V8” key, the “B9” key, the “N?” key, the “M'” and the “.” key.

The bottom row 18 includes seven keys of various sizes and shapes having keys labeled with keyboard symbols or characters as follows. From left to right the bottom row 18 includes the “Num” key of a size similar to the keys in the first three rows, the “[” key of a size about double those keys in the first three rows, the “Ctrl*” key, the “Alt0” key, and the “Ins#” key each of a size similar to the size of the keys in the first three rows, the “]” key of a size about double those keys in the first three rows, and the [symbol] key of a size about equal to those of the first three rows. The “←” key is located in the upper left corner of the keypad, directly above the “Q;” key and symmetrical with the “P” key. A second key having, for example, a keyboard symbol “←” can be located above the top row 12 at the left upper corner thereof as shown in FIG. 1.

It can be appreciated that the keypad as described above and as shown in FIG. 1 provides a central group of numeric keys which are used for typing or entering phone numbers on, for example, a handheld phone 20. The numerals 0, 1, 2, 3, 4, 5, 6, 7, 8, and 9 are located jointly with letters on alphanumeric keys. There is provided a single key for each numeral. The numeric keys are arranged in a standard pattern common to portable keyboard/keypad devices such as cellular and satellite telephones. An operator need not learn a new or non-standard pattern of numbers when using the keypad of FIG. 1.

The “2,” “4” and “6” buttons are located on an integral three-button pad, as are the “5,” “7” and “9” buttons and the “8,” “*” and “#” buttons. The individual buttons are shaped with substantially trapezoidal shapes as seen in FIG. 6. The three-button or three-keypad of FIG. 6 is shaped similar to an inverted “Y” or “V” as are the two pads directly above it as seen in FIG. 1.

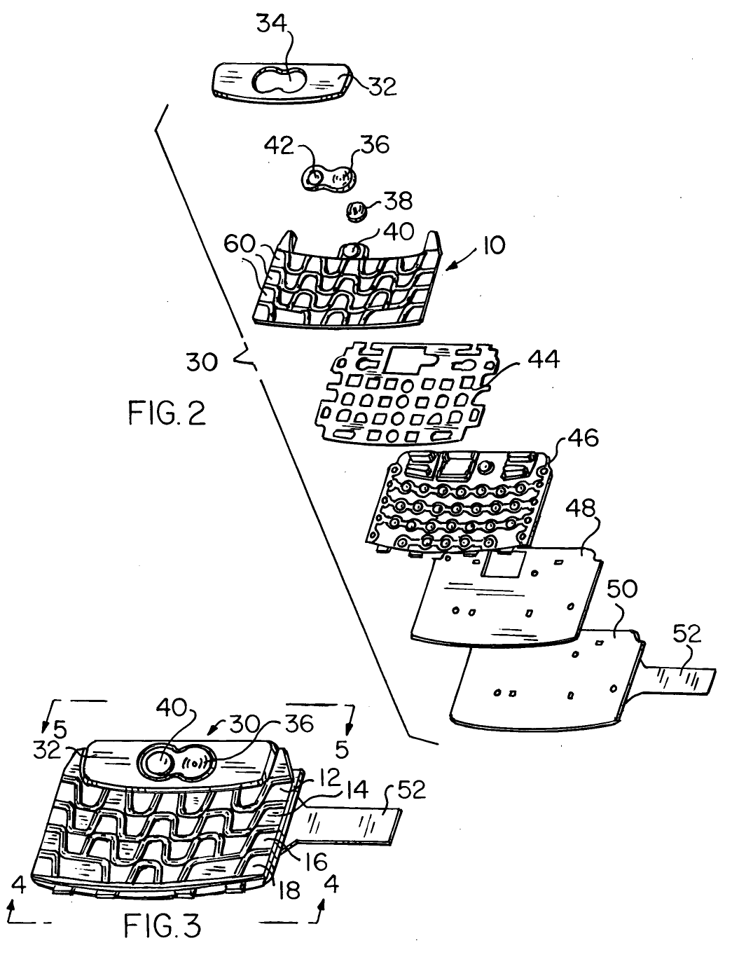

An exploded view of one example of a keypad assembly 30 constructed in accordance with this disclosure is shown in FIG. 2. This assembly includes a user-operated function key 32 for selecting operating functions or modes. The function key 32 has an aperture 34 for receiving a WIFI key 36. A center light 38 is located beneath the WIFI key. A jog ball 40 projects through an aperture 42 in the WIFI key 36 and through the aperture 34 in the function key 32.

A plastic keyboard 10, as described above, overlies a shading film 44. The shading film 44 is superimposed on co-molded rubber pad and light guide 46, which in turn is positioned on a metal dome plate 48. Additional structural details of the co-molded rubber pad and light guide are shown in FIG. 9. The domed plate 48 is formed with a plurality of resilient spring domes aligned under each key on the keyboard 10 to provide a positive but light activation force of each key on the keyboard/keypad 10.

A printed circuit board assembly 50 is aligned with the domes on the domed metal plate 48. A plurality of spring-action domes 70 (FIG. 11) biases the keys on the keypad 10 through the multiple layers of the keypad assembly 30. When assembled as shown in FIG. 3, a compact low profile keypad assembly 30 is formed with keys which are larger than those possible using conventional QWERTY keypad designs and layouts. A flexible connection strip 52 extends from the printed circuit board assembly 50 for electrical connection to a power source and other electronic components.

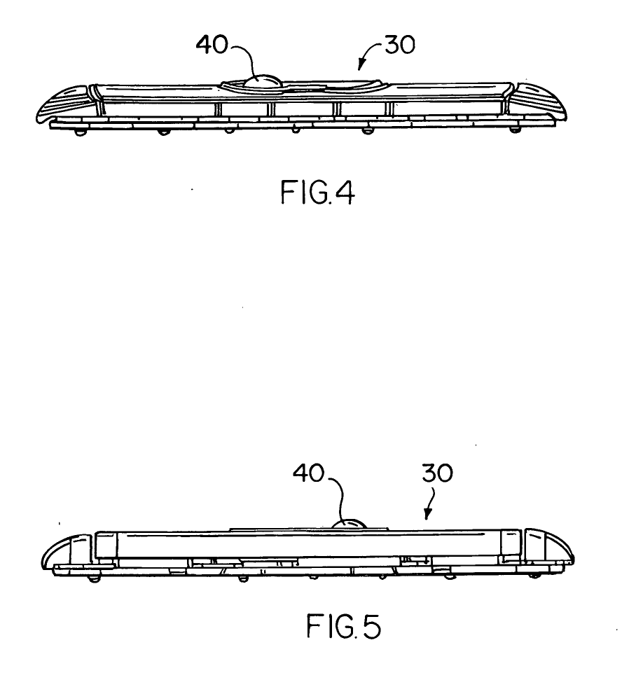

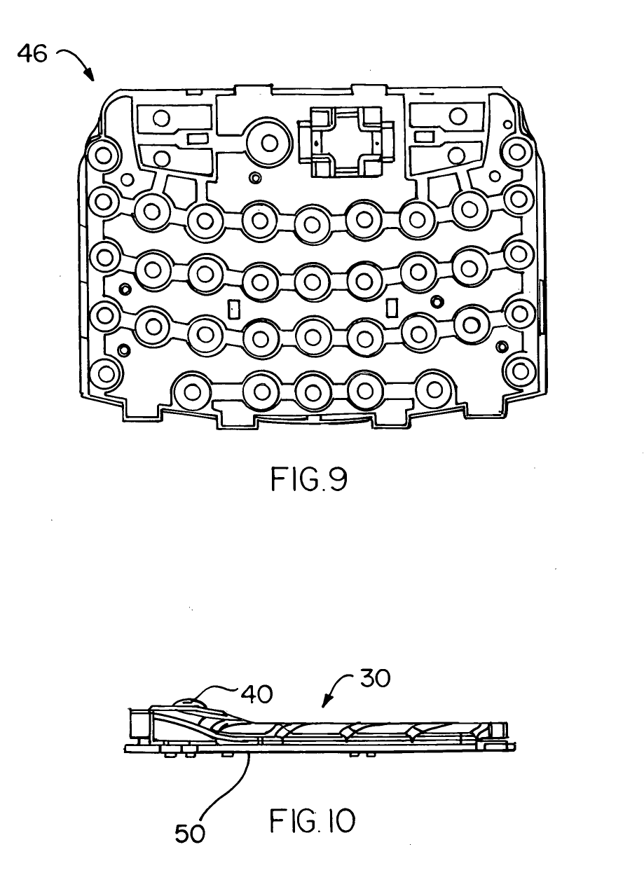

As seen in FIGS. 4 and 5, a very low profile keypad assembly 30 results from the laminated, multi-layer construction shown in FIGS. 2 and 3. Additional details of this construction are shown in the sectional views of FIGS. 7, 8 and 10. The connection strip 52 is not shown in FIGS. 4 and 5.

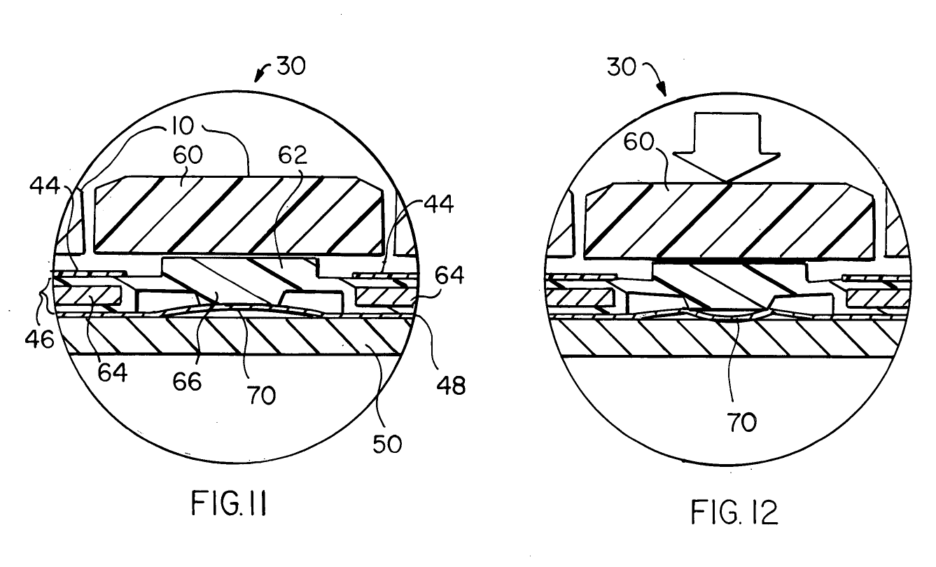

An enlarged sectional view of a portion of the keypad assembly 30 is shown in FIGS. 11 and 12. In FIG. 11, the keypad assembly 30 is shown in an inactivated or “at rest” position, and in FIG. 12, the keypad assembly 30 is shown in a depressed or activated position.

As further seen in FIGS. 11 and 12, one of the keys 60 of the keypad 10 is positioned directly over a raised rubber upper pad 62 co-molded with a light guide insert 64 on the rubber pad and light guide 46. A downwardly-extending rubber pad 66 overlies a metal dome 70 positioned beneath each key 60 on keypad 10. Each metal dome is formed to provide a light but positive spring action and pleasant tactile feel to an operator when activating a key 60 from its position in FIG. 11 to its position in FIG. 12.

By depressing any key 60 on the keypad 10, a respective dome 70 is pressed downwardly into electrical contact with a circuit on circuit board 50 to provide an electrical input to the circuit board as is known in the art. When the key 60 is released, the spring action of the dome 70 returns the key 60 to its at rest position as shown in FIG. 11.

It will be appreciated by those skilled in the art that the above keypad designs are merely representative of the many possible embodiments of the disclosure and that the scope of the disclosure should not be limited thereto. For example, instead of moving the letter P above the letter O as described above, the letter Q can be moved above the letter W in a similar manner, such as to the position of the “←” key shown in FIG. 1, to achieve substantially the same result.

What is claimed is:

1. A keypad, comprising:
a top row of buttons; and
a first button comprising a keyboard letter disposed above said top row of buttons.

2. The keypad of claim 1, wherein said button comprises a letter P button.

3. The keypad of claim 2, wherein said top row of buttons consists of nine buttons.

4. The keypad of claim 3, wherein said top row of buttons extends substantially horizontally across said keypad from a left end portion to a right end portion and wherein said button is disposed above said right end portion.

5. The keypad of claim 1, further comprising a second row of buttons disposed below said top row of buttons, and a third row of buttons disposed below said second row of buttons.

6. The keypad of claim 5, wherein each of said top row, second row and third row consists of nine buttons.

7. The keypad of claim 3, wherein said top row of buttons comprises the Q, W, E, R, T, Y, U, I, and O letter buttons.

8. The keypad of claim 1, wherein at least one of said top row of buttons comprises a substantially trapezoidal shape.

9. The keypad of claim 5, wherein a plurality of said buttons is formed in integral groups of three buttons.

10. The keypad of claim 9, wherein at least one button of one of said integral groups of three buttons is located in said top row and a second and a third button of said at least one of said integral groups of three buttons is located in said second row.

11. The keypad of claim 9, wherein one of said integral groups of three buttons comprises generally V-shaped configuration, and another of said groups of three buttons comprises a generally inverted V-shaped configuration.

12. The keypad of claim 1, wherein said button comprises a letter Q button.

13. The keypad of claim 1, further comprising a second button comprising a keyboard symbol disposed above said top row of buttons.

14. A keypad, comprising:
a top row of nine buttons each comprising a letter; and
a button comprising a keyboard symbol located above said top row.

15. The keypad of claim 14, wherein said button comprises a letter P.
